(19) United States
(12) Patent Application Publication
(10) Pub. No.: US 2011/0024824 A1
(43) Pub. Date: Feb. 3, 2011

(54) NONVOLATILE SEMICONDUCTOR MEMORY DEVICE AND METHOD FOR MANUFACTURING SAME

(75) Inventors: Yasuhiro SHIMURA, Kanagawa-ken (JP); Takashi Izumida, Kanagawa-ken (JP); Mutsuo Morikado, Kanagawa-ken (JP); Kiyomi Naruke, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/820,351

(22) Filed: Jun. 22, 2010

(30) Foreign Application Priority Data
Jul. 28, 2009 (JP) 2009-175731

(51) Int. Cl. H01L 29/792; H01L 21/28

(52) U.S. Cl. 257/324; 438/591; 257/E29.309; 257/E21.21

(57) ABSTRACT

According to one embodiment, a nonvolatile semiconductor memory device includes a semiconductor layer and a transistor. The transistor includes: a source region, a drain region, and a channel region provided in the semiconductor layer, the channel region being between the source and drain regions; a gate insulating film provided on the channel region; a charge layer provided on the gate insulating film, the charge layer having a side portion and a apical portion;

an inter-electrode insulating film covering the side portion and the apical portion; and a control gate provided on the inter-electrode insulating film. The control gate includes: a side-portion conductive layer opposing the side portion; and an apical-portion conductive layer opposing the apical portion.

The apical-portion conductive layer has a work function higher than a work function of the charge layer and higher than a work function of the side-portion conductive layer.

### CROSS-REFERENCE TO RELATED APPLICATIONS

This application is based upon and claims the benefit of priority from the prior Japanese Patent Application No. 2009-175731, filed on Jul. 28, 2009; the entire contents of which are incorporated herein by reference.

### FIELD

Embodiments described herein relate generally to a nonvolatile semiconductor memory device with a material on a floating gate having a small apical portion via an inter-electrode insulating film and a method for manufacturing the same.

### BACKGROUND

In recent years, multiple-value nonvolatile semiconductor memory devices (memory) are being used to reduce costs. As a result, higher programming voltage is used; and leak current from the floating gate to the control gate increases during the programming operation.

Technology is discussed in JP-A 2009-60125 (Kokai) to reduce the leak current by using a control gate having a high work function. However, in this case, a control gate of the same material is used over the upper face and the side face of the floating gate. Therefore, the electric field occurring at the apical portion and the side portion is the same; and there is room for improvement to mitigate the electric field concentration when the floating gate has a small apical portion.

In the case where an inter-electrode insulating film between the floating gate and the control gate is made thicker to reduce the leak current during the programming operation, the coupling ratio decreases. Therefore, the controllability of the channel region by the control gate worsens. Moreover, a thick inter-electrode insulating film makes it difficult to fill the control gate and the inter-electrode insulating film between the floating gates of memory cells. Therefore, improvements to bit density are impeded by constraints arising when reducing the distance between the memory cells.

### BRIEF DESCRIPTION OF THE DRAWINGS

FIGS. 1A and 1B are schematic cross-sectional views illustrating the configuration of a nonvolatile semiconductor memory device according to a first embodiment;

FIGS. 2A to 2F are schematic views illustrating the operations of the nonvolatile semiconductor memory device according to the first embodiment;

FIGS. 3A to 3F are schematic cross-sectional views in order of the processes, illustrating a method for manufacturing the nonvolatile semiconductor memory device according to the first embodiment;

FIGS. 4A and 4B are schematic cross-sectional views illustrating the configuration of the nonvolatile semiconductor memory device according to the first embodiment;

FIGS. 5A and 5B are schematic cross-sectional views illustrating the configuration of another nonvolatile semiconductor memory device according to the first embodiment;

FIGS. 6A and 6B are schematic cross-sectional views illustrating the configuration of another nonvolatile semiconductor memory device according to the first embodiment;

FIGS. 7A and 7B are schematic cross-sectional views illustrating the configuration of a nonvolatile semiconductor memory device according to a second embodiment;

FIGS. 8A and 8B are schematic cross-sectional views illustrating the configuration of another nonvolatile semiconductor memory device according to the second embodiment;

FIGS. 9A and 9B are schematic cross-sectional views illustrating the configuration of another nonvolatile semiconductor memory device according to the second embodiment; and

FIG. 10 is a flowchart illustrating a method for manufacturing the nonvolatile semiconductor memory device according to a third embodiment.

### DETAILED DESCRIPTION

In general, according to one embodiment, a nonvolatile semiconductor memory device includes a semiconductor layer and a first transistor. The first transistor includes a first source region, a first drain region, a first channel region, a first gate insulating film, a first charge layer, a first inter-electrode insulating film, and a first control gate. The first channel region is provided in the semiconductor layer between the first source region and the first drain region. The first gate insulating film is provided on the first channel region. The first charge layer is provided on the first gate insulating film and has a first side portion and a first apical portion. The first inter-electrode insulating film covers the first side portion and the first apical portion. The first control gate is provided on the first inter-electrode insulating film. The first control gate includes a first side-portion conductive layer and a first apical-portion conductive layer. The first side-portion conductive layer opposes the first side portion. The first apical-portion conductive layer opposes the first apical portion. The first apical-portion conductive layer has a work function higher than a work function of the first charge layer and higher than a work function of the first side-portion conductive layer.

According to another embodiment, a method for manufacturing a nonvolatile semiconductor memory device is disclosed. The method includes: forming a charge layer having a side portion and an apical portion and forming an inter-electrode insulating film to cover the side portion and the apical portion; forming a first conductive film on the inter-electrode insulating film; removing a portion of the first conductive film opposing the apical portion to expose an apical portion insulating film of the inter-electrode insulating film opposing the apical portion; and forming a second conductive film on the exposed apical portion insulating film. The second conductive film has a work function higher than a work function of the charge layer and higher than a work function of the first conductive film.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

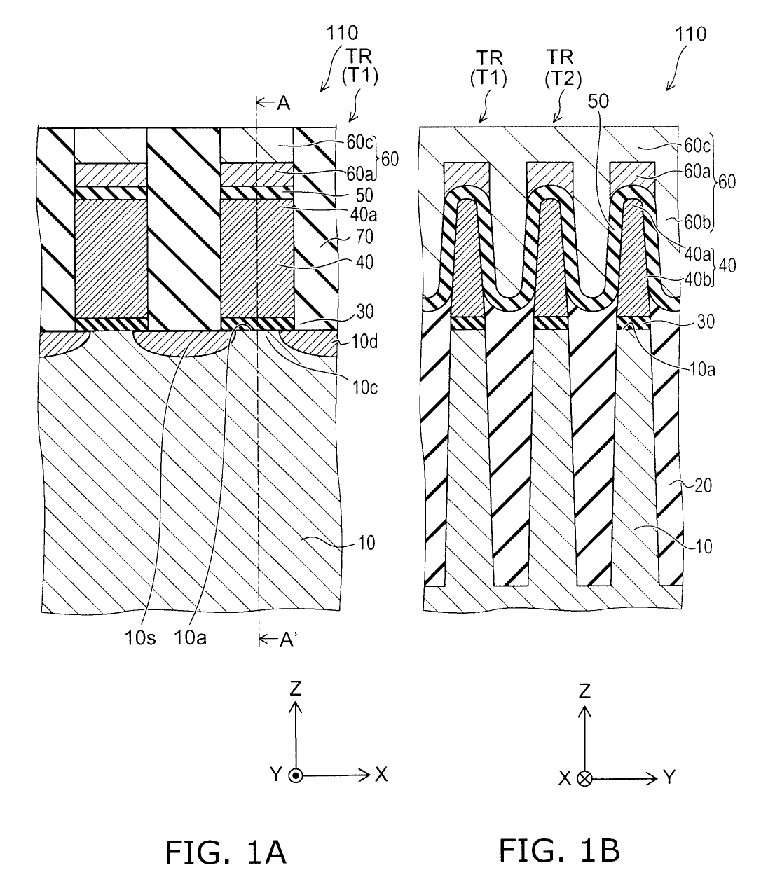

FIGS. 1A and 1B are schematic cross-sectional views illustrating the configuration of a nonvolatile semiconductor memory device according to a first embodiment.

FIG. 1B is a cross-sectional view along line A-A′ of FIG. 1A.

As illustrated in FIGS. 1A and 1B, a nonvolatile semiconductor memory device 110 according to the first embodiment includes a semiconductor layer 10 and a transistor TR provided on the semiconductor layer 10.

The semiconductor layer 10 is, for example, a P-type silicon substrate and/or a well.

The transistor TR includes a source region 10s, a drain region 10d, and a channel region 10c provided in the semiconductor layer 10. The channel region 10c is between the source region 10s and the drain region 10d.

Here, a direction perpendicular to a major surface 10a of the semiconductor layer 10 is taken as a Z axis direction. A direction along which the source region 10s opposes the drain region 10d is taken as an X axis direction (the first direction). A direction perpendicular to the Z axis direction and the X axis direction is taken as a Y axis direction (the second direction).

As illustrated in FIG. 1B, the transistor TR further includes: a gate insulating film 30 provided on the channel region 10c, a floating gate 40 (a charge layer, for example, a charge storing layer) provided on the gate insulating film 30 and having a side portion 40b and an apical portion 40a, an inter-electrode insulating film 50 covering the side portion 40b and the apical portion 40a of the floating gate 40, and a control gate 60 provided on the inter-electrode insulating film 50. The apical portion 40a of the floating gate 40 is smaller than the bottom portion of the floating gate 40 in the Y axis direction.

In other words, the width of the apical portion 40a of the floating gate 40 along the second direction (the Y axis direction) is narrower than the width along the second direction of a portion of the floating gate 40 contacting to the gate insulating film 30 side.

The control gate 60 includes a side-portion conductive layer 60b opposing the side portion 40b of the floating gate 40 and an apical-portion conductive layer 60a opposing the apical portion 40a of the floating gate 40.

The work function of the apical-portion conductive layer 60a is higher than the work function of the floating gate 40 and higher than the work function of the side-portion conductive layer 60b.

Thus, in the control gate 60, different materials may be used in the apical-portion conductive layer 60a opposing the apical portion 40a of the floating gate 40 and the side-portion conductive layer 60b opposing the side portion 40b of the floating gate 40.

The floating gate 40 may include, for example, N⁺ polysilicon having a low work function.

The side-portion conductive layer 60b of the control gate 60 also may include, for example, N⁺ polysilicon.

The apical-portion conductive layer 60a of the control gate 60 may include a material having a work function higher than that of N⁺ polysilicon such as, for example, P⁺ polysilicon, metal (Au, etc.), silicide (CoSi, etc.), a nitride conductive film (TaN, etc.), and an oxide conductive film (ITO (Indium Tin Oxide), etc.).

However, the embodiment is not limited to the description recited above. It is sufficient that the work function of the material used as the apical-portion conductive layer 60a of the control gate 60 is higher than the work function of the material used as the floating gate 40 and higher than the work function of the material used as the side-portion conductive layer 60b of the control gate 60; and any material may be used as each of the apical-portion conductive layer 60a of the control gate 60, the side-portion conductive layer 60b of the control gate 60, and the floating gate 40.

Thereby, leak current from the apical portion 40a of the floating gate 40 to the control gate 60 can be reduced. In particular, the leak current can be reduced in a structure having a small apical portion 40a of the floating gate 40.

The phenomenon of the apical portion 40a of the floating gate 40 thus becoming smaller has become prominent due to the shrinking of memory cells in recent years. In the case where the apical portion 40a of the floating gate 40 is small, even in the case where a large programming voltage is applied to increase a tunneling current of the tunneling insulating film and increase the amount of injected electrons, the increased amount of the injected electrons are emitted to the control gate by a leak current increased by the injected electrons; and, for example, the threshold voltage unfortunately cannot be set to levels necessary for multiple-value memory cells. However, by the configuration of this embodiment, the leak current can be reduced; and the threshold voltage can be set to levels allowing multiple-value memory cells.

As illustrated in FIG. 1A, an inter-layer insulating film 70, for example, covers the X axis direction side faces of the gate insulating film 30, the X axis direction side faces of the floating gate 40, and the X axis direction side faces of the control gate 60.

As illustrated in FIG. 1B, the transistor TR is multiply provided along the Y axis direction. In other words, in addition to a first transistor TR1 (having the same configuration as the transistor TR recited above), the nonvolatile semiconductor memory device 110 further includes a second transistor TR2 (having the same configuration as the transistor TR recited above) provided adjacent to the first transistor TR1 in the Y axis direction.

The semiconductor layer 10 between transistors TR adjacent in the Y axis direction is divided on the major surface 10a side of the semiconductor layer 10 by, for example, an inter-layer insulating film 20.

An upper conductive layer 60c is provided on the side faces and the upper face of the apical-portion conductive layer 60a of each of the multiple transistors TR. The control gate 60 includes the apical-portion conductive layer 60a, the side-portion conductive layer 60b, and the upper conductive layer 60c. The upper conductive layer 60c may include any material. For example, the upper conductive layer 60c may include the same material as the side-portion conductive layer 60b. As described below, the upper conductive layer 60c may include a material having an electrical resistance lower than that of the apical-portion conductive layer 60a.

By such a configuration, the control gate 60 of the multiple transistors TR is continuous along the Y axis direction.

Hereinbelow, the case is described where the same material (e.g., N⁺ polysilicon) having a low work function is used as the floating gate 40 and the side-portion conductive layer 60b of the control gate 60; and a material (e.g., P⁺ polysilicon) having a high work function is used as the apical-portion conductive layer 60a of the control gate 60.

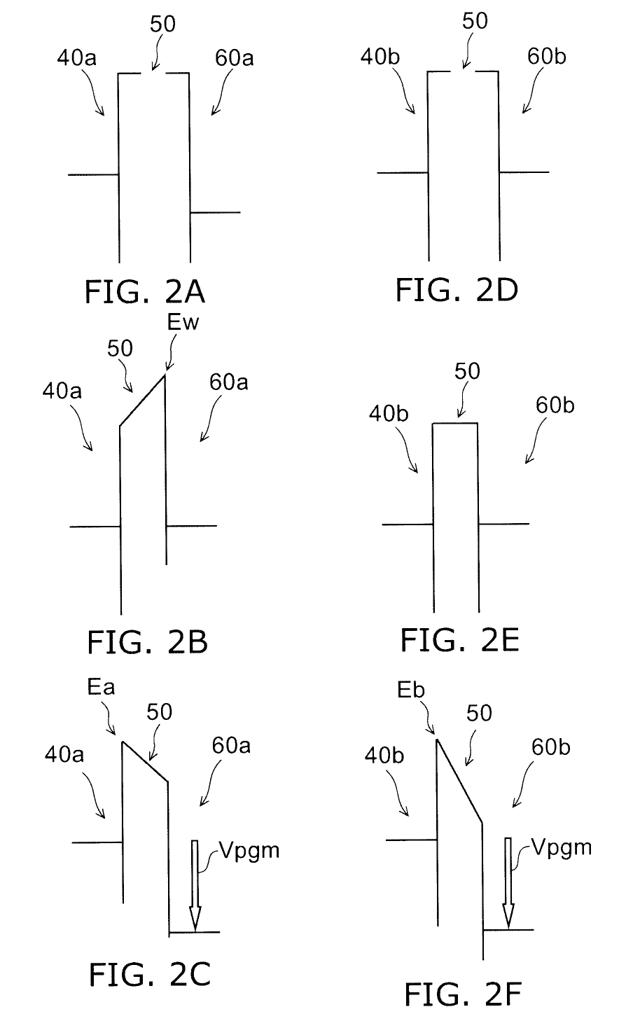

FIGS. 2A to 2F are schematic views illustrating operations of the nonvolatile semiconductor memory device according to the first embodiment.

Namely, these drawings are energy band diagrams of the nonvolatile semiconductor memory device 110. FIGS. 2A to 2C are energy band diagrams of the apical portion 40a and the apical-portion conductive layer 60a. FIGS. 2D to 2F are energy band diagrams of the side portion 40b and the side-portion conductive layer 60b. FIGS. 2A and 2D correspond to the state prior to the floating gate 40 contacting the control gate 60 via the inter-electrode insulating film 50. FIGS. 2B and 2E correspond to the state in which the floating gate 40 contacts the control gate 60 via the inter-electrode insulating film 50. FIGS. 2C and 2F correspond to the state in which a programming voltage Vpgm is applied to the control gate 60.

In the programming operation of the nonvolatile semiconductor memory device 110, a voltage positive with respect to the semiconductor layer 10 is applied to the control gate 60 to perform at least one operation selected from injecting electrons into the floating gate 40 and emitting electron holes from the floating gate 40; and a voltage, i.e., the programming voltage Vpgm, having a positive polarity with respect to the semiconductor layer 10 is applied to the control gate 60. An FN (Fowler-Nordheim) current flows in the gate insulating film 30 due to the application of the programming voltage Vpgm; and electrons are injected from the semiconductor layer 10 into the floating gate 40. In the erasing operation, a voltage having a negative polarity with respect to the control gate 60 is applied to the semiconductor layer 10 to perform at least one operation selected from emitting electrons from the floating gate 40 and injecting electron holes into the floating gate 40.

First, in the side portion 40b of the floating gate 40, operations such as those recited below are performed.

As illustrated in FIGS. 2D and 2E, the work functions of the floating gate 40 (the side portion 40b) and the side-portion conductive layer 60b are the same prior to and after the floating gate 40 contacts the control gate 60 via the inter-electrode insulating film 50. Therefore, the energy level of the side portion 40b and the energy level of the side-portion conductive layer 60b are equal; and an electric field does not occur between the side portion 40b and the side-portion conductive layer 60b.

When the programming voltage Vpgm is applied as illustrated in FIG. 2F, a large electric field Eb occurs between the side portion 40b and the side-portion conductive layer 60b.

On the other hand, operations such as those recited below are performed in the apical portion 40a of the floating gate 40.

As illustrated in FIG. 2A, prior to the floating gate 40 contacting the control gate 60 via the inter-electrode insulating film 50, there is a difference between the energy level of the apical portion 40a and the energy level of the apical-portion conductive layer 60a based on the difference in the work functions of the floating gate 40 (the apical portion 40a) and the apical-portion conductive layer 60a.

As illustrated in FIG. 2B, when the floating gate 40 contacts the control gate 60 via the inter-electrode insulating film 50, an electric field Ew occurs between the apical portion 40a and the apical-portion conductive layer 60a based on the difference in the work functions of the floating gate 40 (the apical portion 40a) and the apical-portion conductive layer 60a. The electric field Ew has the opposite polarity of the electric field occurring due to the application of the writing voltage Vpgm.

As illustrated in FIG. 2C, when the programming voltage Vpgm is applied to the control gate 60, an electric field Ea occurring between the apical portion 40a and the apical-portion conductive layer 60a is mitigated by the electric field Ew caused by the difference in the work functions of the floating gate 40 (the apical portion 40a) and the apical-portion conductive layer 60a.

In other words, the electric field Ea applied between the apical portion 40a and the apical-portion conductive layer 60a when applying the programming voltage Vpgm is more moderate than the electric field Eb applied between the side portion 40b and the side-portion conductive layer 60b.

Thereby, the electric field Ea of the apical portion 40a can be moderate and the leak current can be reduced even if the degree of the electric field concentration in the apical portion 40a increases, when the apical portion 40a of the floating gate 40 is smaller to increase the element density of the nonvolatile semiconductor memory device 110.

As a comparative example, for example, the case is considered where a material having a high work function is used not only as the apical-portion conductive layer 60a opposing the apical portion 40a but also as the side-portion conductive layer 60b opposing the side portion 40b. In such a case, the leak current of the side portion 40b as well as that of the apical portion 40a decreases. However, a depletion layer undesirably forms from the boundary between the side portion 40b and the inter-electrode insulating film 50 into the side portion 40b side or from the boundary between the side-portion conductive layer 60b and the inter-electrode insulating film 50 into the side-portion conductive layer 60b side. As a result, the capacitance of the capacitance element formed of the side portion 40b, the side-portion conductive layer 60b, and the inter-electrode insulating film 50 interposed between the side portion 40b and the side-portion conductive layer 60b undesirably decreases; and the so-called coupling capacitance undesirably decreases. On the other hand, unlike the apical portion 40a, the electric field concentration of the side portion 40b is weak; and the leak amount of the side portion 40b of the floating gate 40 is smaller than that of the apical portion 40a. In other words, in the case where a material having a high work function is used as the side-portion conductive layer 60b, the reduction of the leak current is outweighed by problems due to the reduction of the coupling capacitance.

Conversely, in the nonvolatile semiconductor memory device 110 according to this embodiment, the work function of the apical-portion conductive layer 60a opposing the apical portion 40a is set to be higher than the work function of the side-portion conductive layer 60b opposing the side portion 40b. Thereby, the electric field Ea of the apical portion 40a is relatively reduced with respect to the electric field Eb of the side portion 40b. The electric field applied to the portion of the inter-electrode insulating film 50 opposing the apical portion 40a may be lower than the electric field applied to the portion of the inter-electrode insulating film 50 opposing the side portion 40b. Thereby, the leak current of the apical portion 40a can be reduced and the coupling capacitance reduction can be prevented even if the degree of the electric field concentration in the apical portion 40a increases, when the apical portion 40a of the floating gate 40 is smaller.

Moreover, in the configuration of the nonvolatile semiconductor memory device 110, the coupling ratio is not reduced because it is unnecessary to make the inter-electrode insulating film 50 thicker to reduce the leak current.

Thus, according to the nonvolatile semiconductor memory device 110, the leak current of the apical portion of the floating gate can be reduced while maintaining a high coupling ratio.

Thereby, the threshold voltages of the transistor TR can be improved to levels allowing multiple-value memory cells.

An example of a method for manufacturing the nonvolatile semiconductor memory device 110 will now be described.

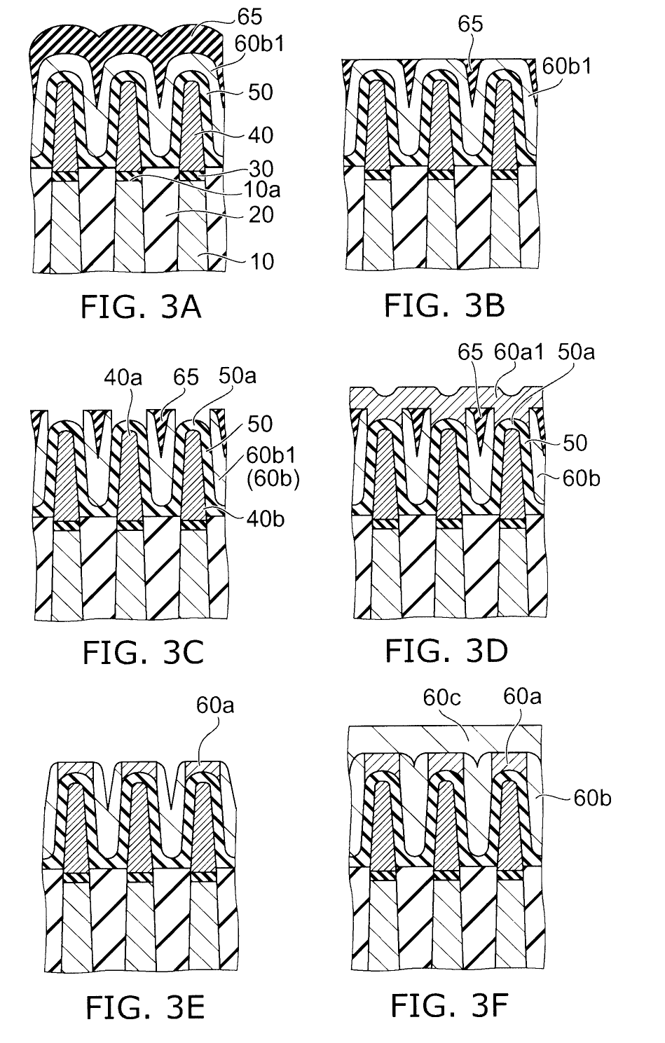

FIGS. 3A to 3F are schematic cross-sectional views in order of the processes, illustrating the method for manufacturing the nonvolatile semiconductor memory device according to the first embodiment. Here, each of FIGS. 3A to 3F is a cross-sectional view corresponding to FIG. 1B.

As illustrated in FIG. 3A, first, a silicon oxide film (SiO₂) forming the gate insulating film 30 is formed with a thickness of 5 nm (nanometers) to 10 nm on the major surface 10a of the P-type semiconductor layer 10. Thereupon, N⁺ polysilicon (e.g., having a P concentration of 1×10¹⁹ cm⁻³ to 1×10²⁰ cm⁻³) forming the floating gate 40 is formed with a thickness of 70 nm. An STI (Shallow Trench Isolation) trench is made by lithography and RIE (Reactive Ion Etching). A silicon oxide film, for example, is formed in the trench by CVD (Chemical Vapor Deposition) and planarized by CMP (Chemical Mechanical Polishing) to form the inter-layer insulating film 20. The upper portion of the inter-layer insulating film 20 is etched such that the upper face of the inter-layer insulating film 20 is lower than the upper face of the floating gate 40 and higher than the upper face of the gate insulating film 30.

A silicon oxide film or an ONO (Oxide Nitride Oxide) film forming the inter-electrode insulating film 50 is formed with a thickness of not less than 10 nm and not more than 15 nm. Thereupon, an N⁺-type polysilicon film 60b1 (e.g., having a P concentration of 1×10¹⁹ cm⁻³ to 1×10²⁰ cm⁻³) forming the side-portion conductive layer 60b of the control gate 60 is formed with a thickness of 15 nm. Here, the space between the floating gates 40 is not completely filled with the N⁺-type polysilicon film 60b1, and a hollow sandwiched in the N⁺-type polysilicon film 60b1 is made between the floating gates 40. A SiN film is formed as a stopper film 65 with a thickness of 30 nm on the N⁺-type polysilicon film 60b1. Here, the stopper film 65 is buried also in the hollow sandwiched in the N⁺-type polysilicon film 60b1.

As illustrated in FIG. 3B, the stopper film 65 is polished by, for example, CMP to expose the upper face of the N⁺-type polysilicon film 60b1 forming the side-portion conductive layer 60b. Here, the stopper film 65 remains only in the hollow sandwiched in the N⁺-type polysilicon film 60b1.

As illustrated in FIG. 3C, the portion of the N⁺-type polysilicon film 60b1 not covered with the stopper film 65 is removed by, for example, RIE. Thereby, the portion of the inter-electrode insulating film 50 (i.e., an apical portion insulating film 50a) opposing the apical portion 40a of the floating gate 40 is exposed.

As illustrated in FIG. 3D, a P⁺-type polysilicon film 60a1, for example, as the apical-portion conductive layer 60a is formed on the exposed inter-electrode insulating film 50 (i.e., the apical portion insulating film 50a) and on the stopper film 65.

As illustrated in FIG. 3E, the P⁺-type polysilicon film 60a1 is polished to the height of the stopper film 65 by, for example, CMP to divide the P⁺-type polysilicon film 60a1 into each portion opposing the apical portion 40a. Thereby, the divided apical-portion conductive layer 60a is formed. The stopper film 65 is removed.

As illustrated in FIG. 3F, an N⁺-type polysilicon film (e.g., having a P concentration of 1×10¹⁹ cm⁻³ to 1×10²⁰ cm⁻³), for example, forming the upper conductive layer 60c is formed on the apical-portion conductive layer 60a, on the side-portion conductive layer 60b, and on the side faces of the side-portion conductive layer 60b between adjacent elements.

The films recited above are appropriately patterned; impurities are implanted to form the source region 10s and the drain region 10d; the inter-layer insulating film 70 is formed; and the nonvolatile semiconductor memory device 110 illustrated in FIGS. 1A and 1B is constructed.

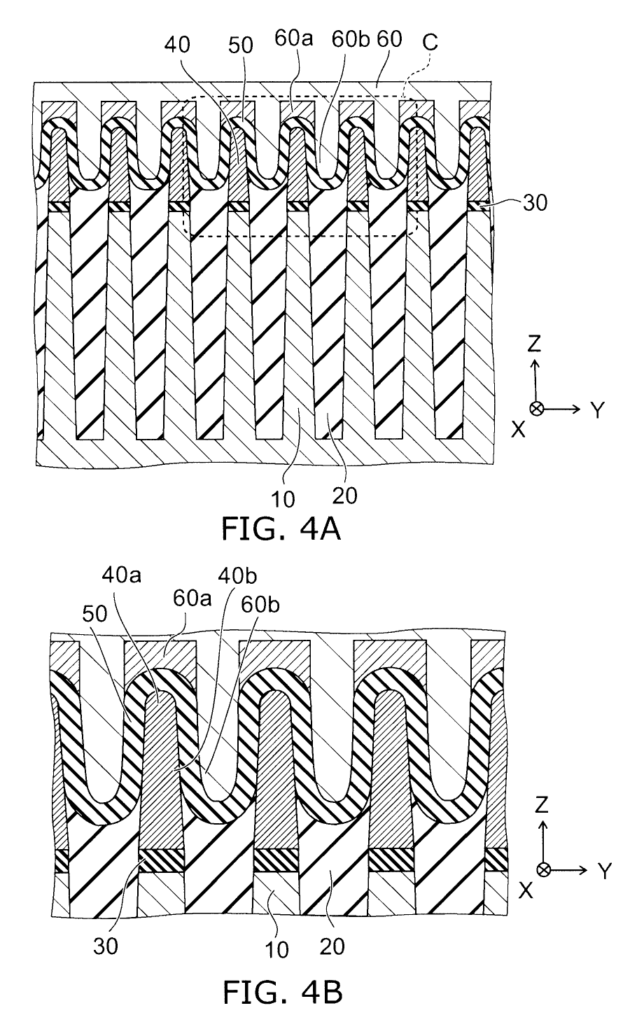

FIGS. 4A and 4B are schematic cross-sectional views illustrating the configuration of the nonvolatile semiconductor memory device according to the first embodiment.

FIG. 4B is an enlarged schematic cross-sectional view of portion C of FIG. 4A.

As illustrated in FIGS. 4A and 4B, the element density of the nonvolatile semiconductor memory device 110 is high; the width (the length in the Y axis direction) of the floating gate 40 is narrower than the height (the length in the Z axis direction); and the aspect ratio of the floating gate 40 is high. In other words, the length of the floating gate 40 in the Z axis direction (the length along a direction from the gate insulating film 30 toward the floating gate 40) is longer than the length of the floating gate 40 along the Y axis direction (the length along the second direction orthogonal to the first direction and a direction from the gate insulating film 30 toward the floating gate 40, where the first direction is a direction along which the first source region 10s opposes the first drain region 10d).

Thus, the apical portion 40a of the floating gate 40 is rounded in the case where the floating gate 40 is small. In the case where the element density is increased further while keeping the height constant, the floating gate 40 becomes smaller; and the apical portion 40a becomes pointed. In other words, the upper face of the apical portion 40a is not a planar surface.

In other words, the curvature of the upper face (the face on the side opposite to the semiconductor layer 10) of the apical portion 40a is greater than the curvature of the side face of the side portion 40b. The curvature is the reciprocal of the curvature radius. Therefore, the curvature radius of the upper face of the apical portion 40a is smaller than the curvature radius of the side face of the side portion 40b.

Thus, although the electric field concentration of the apical portion 40a is strong and the leak current increases in the case where the curvature radius of the apical portion 40a is small. On the other hand, in the nonvolatile semiconductor memory device 110 according to this embodiment, the electric field of the portion of the apical portion 40a can be effectively reduced by using the apical-portion conductive layer 60a having a high work function in the portion of the control gate 60 opposing the apical portion 40a; and the leak current can be reduced.

The boundary between the apical portion 40a and the side portion 40b of the floating gate 40 may be taken to be a location where, for example, the curvature of the upper face of the floating gate 40 starts to change. Alternatively, the boundary may be taken to be a location where, for example, the change rate of the curvature of the upper face of the floating gate 40 is a maximum.

In other words, it is sufficient that the apical portion 40a includes a curved surface portion (i.e., a portion where the degree of the electric field concentration is strong) of the upper side of the floating gate 40. Accordingly, it is sufficient that the apical-portion conductive layer 60a is provided to at least oppose the curved surface portion of the upper side of the floating gate 40.

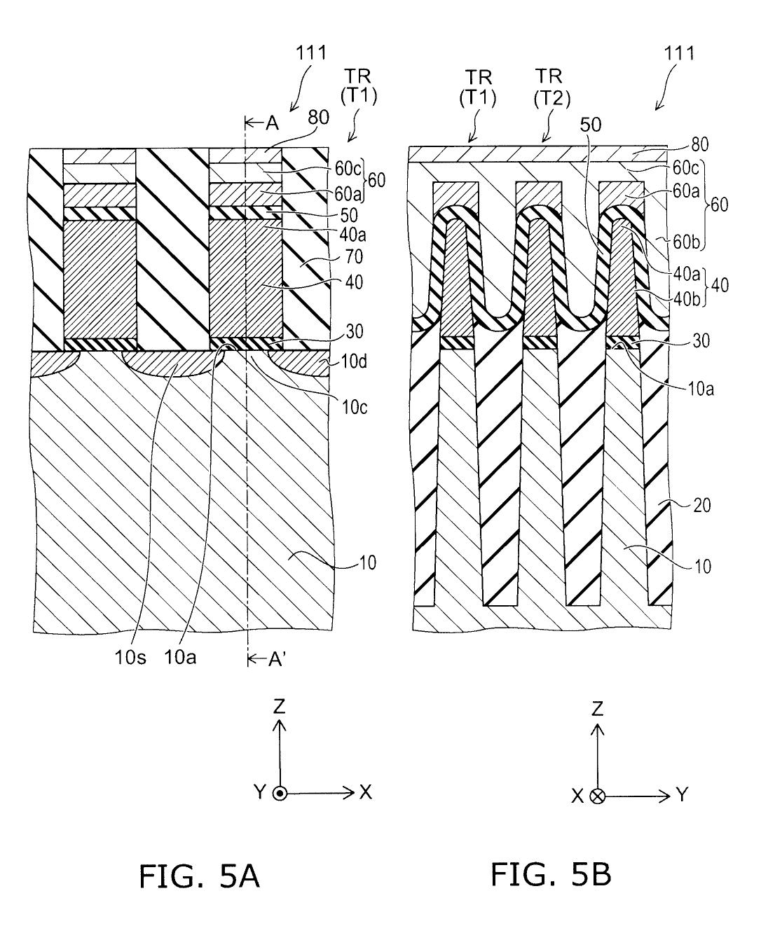

FIGS. 5A and 5B are schematic cross-sectional views illustrating the configuration of another nonvolatile semiconductor memory device according to this embodiment.

In another nonvolatile semiconductor memory device 111 according to this embodiment, an electrode film 80 having a low resistance is provided on the upper conductive layer 60c as illustrated in FIGS. 5A and 5B. Hereafter, the electrode film 80 may be called a low resistance film 80. Here, the low resistance film 80 is formed from a material having a resistivity lower than resistivities of the side-portion conductive layer 60b and the upper conductive layer 60c.

The low resistance film 80 may include, for example, various silicides and various metals.

Thereby, a delay of the electrical signal applied to the control gate 60 can be suppressed; and stable operations can be realized. In particular, effects are greater in the case where a material having a high resistivity, e.g., TaN or TiN, is used as the apical-portion conductive layer 60a.

Although the low resistance film 80 is illustrated as an entity separate from the control gate 60 in FIGS. 5A and 5B, the low resistance film 80 may be included in the control gate 60.

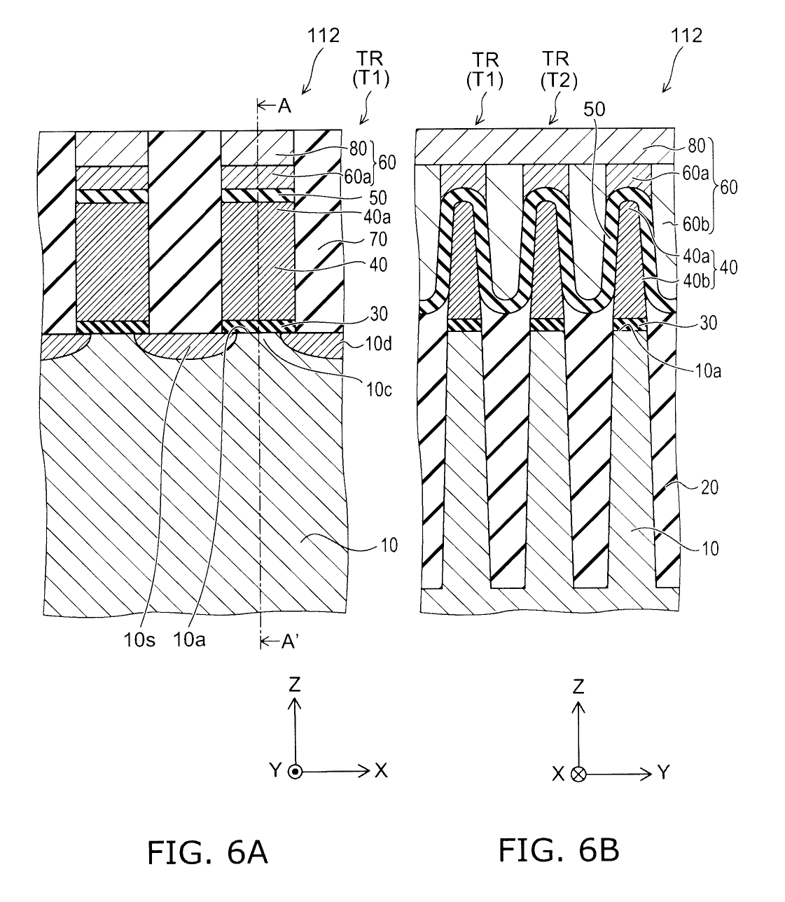

FIGS. 6A and 6B are schematic cross-sectional views illustrating the configuration of another nonvolatile semiconductor memory device according to the first embodiment.

In another nonvolatile semiconductor memory device 112 according to this embodiment, the upper conductive layer 60c is not provided; and the low resistance film 80 is provided on the apical-portion conductive layer 60a as illustrated in FIGS. 6A and 6B.

In such a case as well, a delay of the electrical signal applied to the control gate 60 can be suppressed; and stable operations can be realized. In particular, effects are greater in the case where a material having a high resistivity, e.g., TaN or TiN, is used as the apical-portion conductive layer 60a. Also, in the case where the apical-portion conductive layer 60a has a thickness equal to a thickness of a total of the apical-portion conductive layer 60a and the upper conductive layer 60c shown in FIG. 5B, the film thickness of the upper conductive layer 60c is replaced with the low resistance film 80. Therefore, the delay of the electrical signal applied to the control gate 60 can be suppressed further; and more stable operations can be realized. Thus, the transistor TR of the nonvolatile semiconductor memory devices 111 and 112 further includes the low resistance film 80 provided on the apical-portion conductive layer 60a and having an electrical resistance lower than that of the apical-portion conductive layer 60a.

### Second Embodiment

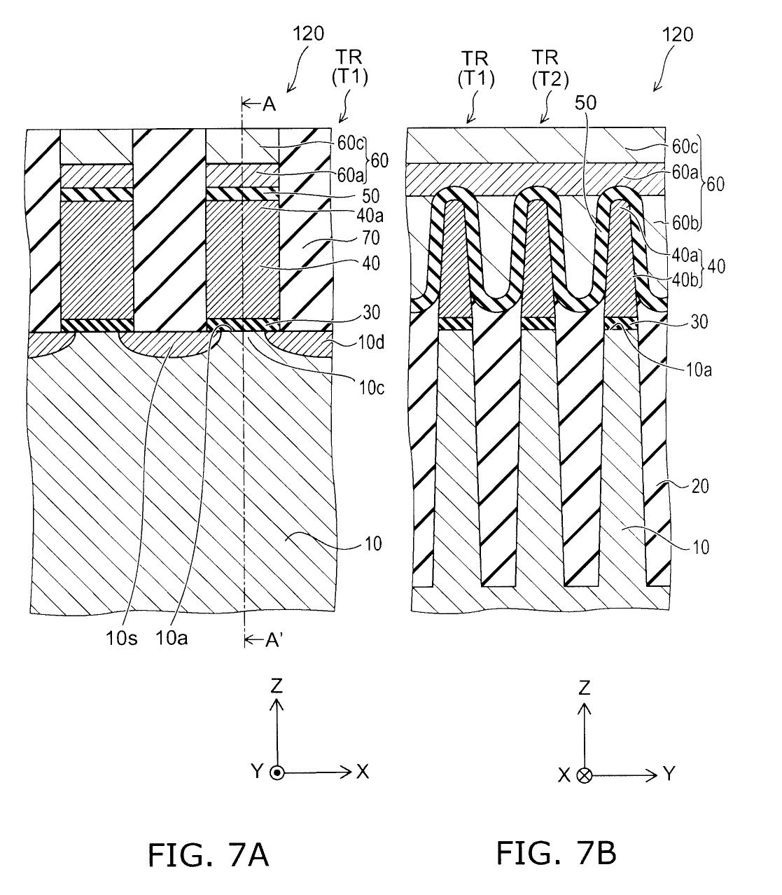

FIGS. 7A and 7B are schematic cross-sectional views illustrating the configuration of a nonvolatile semiconductor memory device according to a second embodiment.

In a nonvolatile semiconductor memory device 120 according to the second embodiment, the apical-portion conductive layer 60a is continuous between adjacent transistors TR as illustrated in FIGS. 7A and 7B. Otherwise, the nonvolatile semiconductor memory device 120 is similar to the nonvolatile semiconductor memory device 110, and a description is omitted.

In other words, the nonvolatile semiconductor memory device 120 includes the semiconductor layer 10, the first transistor TR1, and the second transistor TR2.

The first transistor TR1 includes a first source region, a first drain region, and a first channel region provided in the semiconductor layer 10, where the first channel region is between the first source region and the first drain region; a first gate insulating film provided on the first channel region; a first charge storing layer (e.g., a first floating gate) provided on the first gate insulating film, where the first charge storing layer has a first side portion and a first apical portion; a first inter-electrode insulating film covering the first side portion and the first apical portion; and a first control gate provided on the first inter-electrode insulating film.

The first control gate includes a first side-portion conductive layer opposing the first side portion and a first apical-portion conductive layer opposing the first apical portion and having a work function higher than a work function of the first charge storing layer and higher than a work function of the first side-portion conductive layer.

The second transistor TR2 is provided adjacent to the first transistor TR1 in the second direction (the Y axis direction) orthogonal to the first direction (the X axis direction) along which the first source region opposes the first drain region.

The second transistor TR2 includes: a second source region, a second drain region, and a second channel region provided in the semiconductor layer 10, where the second drain region opposes the second source region in the first direction and the second channel region is between the second source region and the second drain region; a second gate insulating film provided on the second channel region; a second charge storing layer (e.g., a second floating gate) provided on the second gate insulating film and having a second side portion and a second apical portion; a second inter-electrode insulating film covering the second side portion and the second apical portion; and a second control gate provided on the second inter-electrode insulating film.

The second control gate includes: a second side-portion conductive layer opposing the second side portion; and a second apical-portion conductive layer provided continuously with the first apical-portion conductive layer to oppose the second apical portion, where the second apical-portion conductive layer has a work function higher than a work function of the second charge storing layer and higher than a work function of the second side-portion conductive layer.

Thus, the apical-portion conductive layer 60a of each of the transistors TR may be provided continuously; and the apical-portion conductive layer 60a may extend also over the side-portion conductive layer 60b between the transistors TR. The nonvolatile semiconductor memory device 120 may be constructed, for example, by omitting the processing described in regard to FIG. 3E.

In such a case as well, the leak current of the apical portion of the floating gate can be reduced while maintaining the coupling ratio. Also, the upper face of the apical portion 40a of the floating gate 40 can be widely covered. In other words, the apical-portion conductive layer 60a may be formed proximally to the boundary between the apical portion 40a and the side portion 40b of the floating gate 40 to further reduce the leak current of the apical portion 40a of the floating gate 40.

In the nonvolatile semiconductor memory devices 110 and 120, the upper conductive layer 60c may be omitted. By using silicide (CoSi, etc.) as the apical-portion conductive layer 60a in such a case, the leak current of the apical portion 40a of the floating gate 40 can be reduced; the resistance of the control gate 60 can be reduced; the delay of the electrical signal of the control gate 60 can be suppressed; and stable operations can be realized.

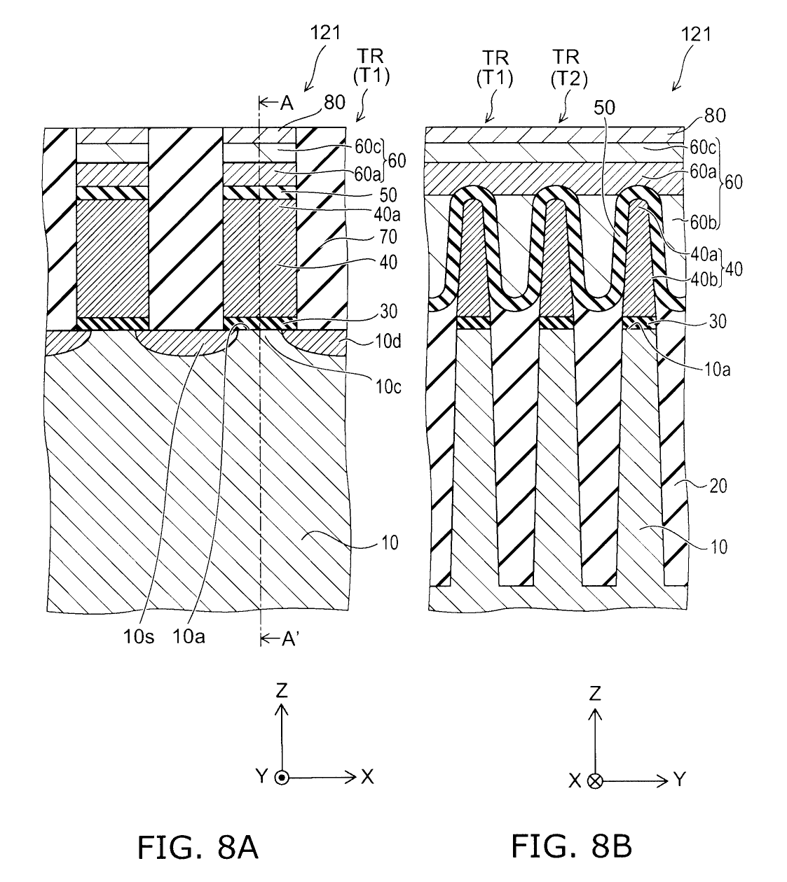

FIGS. 8A and 8B are schematic cross-sectional views illustrating the configuration of another nonvolatile semiconductor memory device according to the second embodiment.

In another nonvolatile semiconductor memory device 121 according to this embodiment, the low resistance film 80 is provided on the upper conductive layer 60c as illustrated in FIGS. 8A and 8B.

In such a case as well, the low resistance film 80 may include, for example, various silicides and various metals.

Thereby, the delay of the electrical signal applied to the control gate 60 can be suppressed; and stable operations can be realized. In particular, effects are greater in the case where a material having a high resistivity, e.g., TaN or TiN, is used as the apical-portion conductive layer 60a.

Although the low resistance film 80 is illustrated as an entity separate from the control gate 60 in FIGS. 8A and 8B, the low resistance film 80 may be included in the control gate 60.

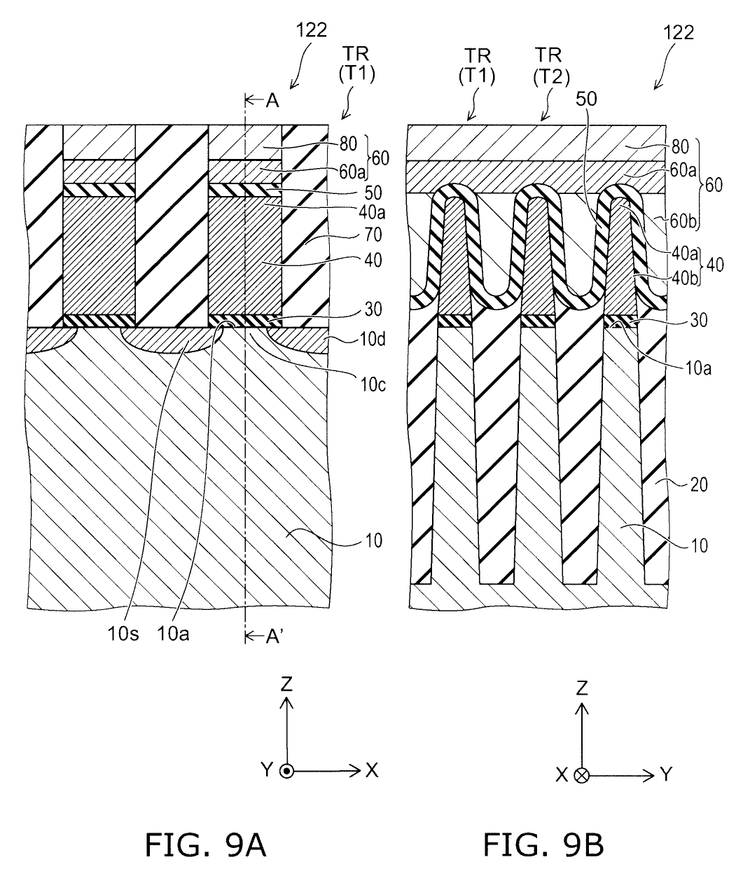

FIGS. 9A and 9B are schematic cross-sectional views illustrating the configuration of another nonvolatile semiconductor memory device according to the second embodiment.

In another nonvolatile semiconductor memory device 122 according to this embodiment, the upper conductive layer 60c is not provided; and the low resistance film 80 is provided on the apical-portion conductive layer 60a as illustrated in FIGS. 9A and 9B.

In such a case as well, the delay of the electrical signal applied to the control gate 60 can be suppressed; and stable operations can be realized. In particular, effects are greater in the case where a material having a high resistivity, e.g., TaN and TiN, are used as the apical-portion conductive layer 60a. Also, in the case where the apical-portion conductive layer 60a has a thickness equal to a thickness of a total of the apical-portion conductive layer 60a and the upper conductive layer 60c shown in FIG. 7B, the film thickness of the upper conductive layer 60c is replaced with the low resistance film 80. Therefore, a delay of the electrical signal applied to the control gate 60 can be suppressed further; and more stable operations can be realized.

Thus, the transistor TR (the first transistor TR1 and the second transistor TR2) of the nonvolatile semiconductor memory devices 121 and 122 further includes the low resistance film 80 provided on the apical-portion conductive layer 60a and having an electrical resistance lower than that of the apical-portion conductive layer 60a.

### Third Embodiment

A method for manufacturing a nonvolatile semiconductor memory device according to a third embodiment is a method for manufacturing a device including the semiconductor layer 10 and the transistor TR. The transistor TR includes: the source region 10s, the drain region 10d, and the channel region 10c provided in the semiconductor layer 10, where the channel region 10c is between the source region 10s and the drain region 10d; the gate insulating film 30 provided on the channel region 10c; a charge storing layer (e.g., the floating gate 40) provided on the gate insulating film 30, where the charge layer has the side portion 40b and the apical portion 40a; the inter-electrode insulating film 50 covering the side portion 40b and the apical portion 40a; and the control gate 60 provided on the inter-electrode insulating film 50. The control gate 60 includes the side-portion conductive layer 60b opposing the side portion 40b and the apical-portion conductive layer 60a opposing the apical portion 40a and having a work function higher than a work function of the charge storing layer and higher than a work function of the side-portion conductive layer 60b.

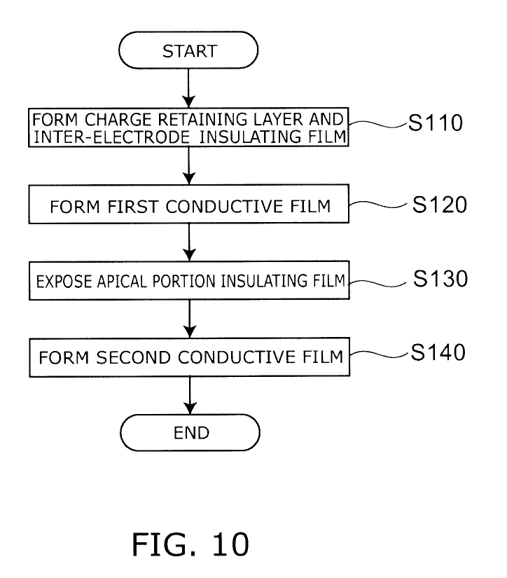

FIG. 10 is a flowchart illustrating the method for manufacturing the nonvolatile semiconductor memory device according to the third embodiment.

This manufacturing method is a method for manufacturing the nonvolatile semiconductor memory device according to either the first or second embodiment.

In the method for manufacturing the nonvolatile semiconductor memory device according to this embodiment, first, a charge storing layer (the floating gate 40) having the side portion 40b and the apical portion 40a is formed; and the inter-electrode insulating film 50 is formed to cover the side portion 40b and the apical portion 40a as illustrated in FIG. 10 (step S110).

A first conductive film forming the side-portion conductive layer 60b is formed on the inter-electrode insulating film 50 (step S120).

In other words, the processing described in regard to FIG. 3A is performed. In the specific example illustrated in FIG. 3A, N⁺ polysilicon may be used as the floating gate 40 recited above and the N⁺-type polysilicon film 60b1 may be used as the first conductive film recited above.

The portion of the first conductive film opposing the apical portion 40a is removed to expose the portion (i.e., the apical portion insulating film 50a) of the inter-electrode insulating film 50 opposing the apical portion 40a (step S130).

In other words, the processing described in regard to FIGS. 3B and 3C is performed.

The second conductive film forming the apical-portion conductive layer 60a and having a work function higher than the work function of the charge storing layer (the floating gate 40) and higher than the work function of the first conductive film is formed on the exposed apical portion insulating film 50a (step S140).

In other words, the processing described in regard to FIG. 3D is performed. In the specific example illustrated in FIG. 3D, the P⁺-type polysilicon film 60a1, for example, forming the apical-portion conductive layer 60a may be used as the second conductive film.

After various processes, the nonvolatile semiconductor memory devices 110 to 112 and 120 to 122 according to the first and second embodiments and nonvolatile semiconductor memory devices having modifications thereof can be manufactured.

According to this manufacturing method, a nonvolatile semiconductor memory device can be manufactured having reduced leak current of the apical portion of the floating gate while maintaining a high coupling ratio. By omitting the process described in regard to FIG. 3E after step S140 recited above, the nonvolatile semiconductor memory device according to the second embodiment can be manufactured. Thereby, the number of manufacturing processes can be lower than that of the first embodiment.

Although the case is described in the embodiments recited above where a floating gate is used as the charge storing layer, the embodiment is not limited thereto. Any configuration may be used in which a charge is stored and emitted. For example, a charge storage layer made of various insulating films may be used as the charge storing layer, and a transistor configuration having a MONOS (Metal Oxide Nitride Oxide Semiconductor) structure, for example, may be used.

Hereinabove, exemplary embodiments of the invention are described with reference to specific examples. However, the invention is not limited to these specific examples. For example, one skilled in the art may appropriately select specific configurations of components of nonvolatile semiconductor memory devices such as semiconductor layers, source regions, drain regions, channel regions, gate insulating films, floating gates, charge layers, charge storing layers, inter-electrode insulating films, control gates, side-portion conductive layers, apical-portion conductive layers, conductive films, low resistance films, electrode films, inter-layer insulating films, and the like from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all nonvolatile semiconductor memory devices and methods for manufacturing nonvolatile semiconductor memory devices practicable by an appropriate design modification by one skilled in the art based on the nonvolatile semiconductor memory devices and the methods for manufacturing nonvolatile semiconductor memory devices described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention. For example, additions, deletions, or design modifications of components or additions, omissions, or condition modifications of processes appropriately made by one skilled in the art in regard to the embodiments described above are within the scope of the invention to the extent that the purport of the invention is included.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A nonvolatile semiconductor memory device, comprising:
a semiconductor layer; and
a first transistor,
the first transistor including:
a first source region, a first drain region, and a first channel region provided in the semiconductor layer, the first channel region being between the first source region and the first drain region;
a first gate insulating film provided on the first channel region;
a first charge layer provided on the first gate insulating film, the first charge layer having a first side portion and a first apical portion;
a first inter-electrode insulating film covering the first side portion and the first apical portion; and
a first control gate provided on the first inter-electrode insulating film,
the first control gate including:
a first side-portion conductive layer opposing the first side portion; and
a first apical-portion conductive layer opposing the first apical portion and having a work function higher than a work function of the first charge layer and higher than a work function of the first side-portion conductive layer.

2. The device according to claim 1, wherein a width of the first apical portion of the first charge layer along a second direction is narrower than a width of the first charge layer contacting to the first gate insulating film side along the second direction, the second direction being orthogonal to a first direction and a direction from the first gate insulating film toward the first charge layer, the first direction being an opposing direction of the first source region and the first drain region.

3. The device according to claim 2, wherein a length of the first charge layer along a direction from the first gate insulating film toward the first charge layer is longer than a length of the first charge layer along a second direction.

4. The device according to claim 1, wherein the first charge layer includes polysilicon.

5. The device according to claim 1, wherein the first charge layer includes N⁺ polysilicon.

6. The device according to claim 1, wherein the first side-portion conductive layer includes N⁺ polysilicon.

7. The device according to claim 6, wherein the first apical-portion conductive layer includes at least one selected from P⁺ polysilicon, metal, silicide, a nitride conductive film, and an oxide conductive film.

8. The device according to claim 7, wherein the metal includes Au, the silicide includes CoSi, the nitride conductive film includes TaN, and the oxide conductive film includes indium tin oxide.

9. The device according to claim 1, wherein a curvature of a face of the first apical portion on a side opposite to the semiconductor layer is greater than a curvature of a side face of the first side portion.

10. The device according to claim 1, wherein an electric field applied to a portion of the first inter-electrode insulating film opposing the first apical portion is lower than an electric field applied to a portion of the first inter-electrode insulating film opposing the first side portion.

11. The device according to claim 1, further comprising: an inter-layer insulating film covering a side face of the first gate insulating film on a first direction side, a side face of the first charge layer on the first direction side, and a side face of the first control gate on the first direction side, the first direction being an opposing direction of the first source region and the first drain region.

12. The device according to claim 1, wherein the first transistor further includes an electrode film provided on the first apical-portion conductive layer and having an electrical resistance lower than an electrical resistance of the first apical-portion conductive layer.

13. The device according to claim 12, wherein
the first apical-portion conductive layer includes at least one selected from TaN and TiN, and
the electrode film includes at least one selected from silicide and metal.

14. The device according to claim 1, further comprising a second transistor provided adjacent to the first transistor in a second direction, the second direction being orthogonal to a first direction and a direction from the first gate insulating film toward the first charge layer, the first direction being an opposing direction of the first source region and the first drain region,
the second transistor including:
a second source region, a second drain region, and a second channel region provided in the semiconductor layer, the second drain region opposing the second source region in the first direction, the second channel region being between the second source region and the second drain region;
a second gate insulating film provided on the second channel region;
a second charge layer provided on the second gate insulating film, the first charge layer having a second side portion and a second apical portion;
a second inter-electrode insulating film covering the second side portion and the second apical portion; and
a second control gate provided on the second inter-electrode insulating film, the second control gate including:
a second side-portion conductive layer opposing the second side portion; and
a second apical-portion conductive layer provided to oppose the second apical portion, the second apical-portion conductive layer having a work function higher than a work function of the second charge layer and higher than a work function of the second side-portion conductive layer and provided continuously with the first apical-portion conductive layer.

15. The device according to claim 14, wherein
the first transistor further includes a first electrode film provided on the first apical-portion conductive layer and having an electrical resistance lower than an electrical resistance of the first apical-portion conductive layer, and
the second transistor further includes a second electrode film provided continuously with the first electrode film on the second apical-portion conductive layer and having an electrical resistance lower than an electrical resistance of the second apical-portion conductive layer.

16. A method for manufacturing a nonvolatile semiconductor memory device comprising:
forming a charge layer having the side portion and an apical portion and forming an inter-electrode insulating film to cover the side portion and the apical portion;
forming a first conductive film on the inter-electrode insulating film;
removing a portion of the first conductive film opposing the apical portion to expose an apical portion insulating film of the inter-electrode insulating film opposing the apical portion; and
forming a second conductive film on the exposed apical portion insulating film, the second conductive film having a work function higher than a work function of the charge layer and higher than a work function of the first conductive film.

17. The method according to claim 16, wherein:
the forming the charge layer includes forming a plurality of the charge layers, and the forming the first conductive film includes forming a hollow of the first conductive film between the charge layers and forming a stopper film in the hollow.

18. The method according to claim 16, wherein a width of the apical portion of the charge layer along a second direction is narrower than a width of the charge layer contacting to the gate insulating film side along the second direction in the forming of the charge layer, the second direction being orthogonal to a first direction and a direction from the gate insulating film toward the charge layer, the first direction being an opposing direction of the source region and the drain region.
